(19) United States
(12) Patent Application Publication
(10) Pub. No.: US 2007/0178676 A1
(43) Pub. Date: Aug. 2, 2007

(54) Method of forming semiconductor multi-layered structure

(75) Inventor: Katsuya Oda, Hachioji (JP)

Correspondence Address: MILES & STOCKBRIDGE PC, 1751 PINNACLE DRIVE, SUITE 500, MCLEAN, VA, 22102-3833, US

(73) Assignee: Hitachi, Ltd.

(21) Appl. No.: 11/655,138

(22) Filed: Jan. 19, 2007

(30) Foreign Application Priority Data
Jan. 30, 2006 (JP) 2006-020513

(51) Int. Cl. H01L 21/20; H01L 33/00; H01L 21/36

(52) U.S. Cl. 438/502

(57) ABSTRACT

Disclosed herein is a method of forming a single crystal SiC on a Si Substrate wherein a SiGe layer lower in melting point than Si and SiC and an amorphous SiC are formed on the Si layer and this structure is annealed at a temperature higher than the melting point of SiGe to relieve strain between SiC and the Si substrate and to cause an amorphous SiC to crystallize at the same time, thereby forming the single crystal SiC layer good in crystallinity and surface morphology.

### CLAIM OF PRIORITY

The present application claims priority from Japanese application JP 2006-020513 filed on Jan. 30, 2006, the content of which is hereby incorporated by reference in this application.

### FIELD OF THE INVENTION

The present invention relates to a method of forming a single crystal semiconductor multi-layered structure different in lattice constant from a single crystal substrate, and in particular, to a method of forming a single crystal SiC on a Si substrate.

### BACKGROUND OF THE INVENTION

A SiC substrate is promising as a material suited for a FET using a SiC as a low loss power device and a white LED based on GaN, however, has the drawback that it is more expensive than other materials, therefore, a technique of forming a high-quality single crystal SiC on a low-cost Si substrate has been developed. A homoepitaxial growth for forming a single crystal SiC on a SiC substrate is conducted generally at about 1500° C. However, a growth temperature needs to be lowered to 1420° C. or less which is a melting point of Si in order to use Si as a substrate. Difference in lattice constant between Si and SiC is as large as about 20%. For this reason, it has been very difficult to form a SiC layer good in crystallinity because a large number of defects occur due to the great difference in lattice constant. A conventional method of forming a SiC single crystal semiconductor thin film on a Si substrate has been set forth, for example, in Materials Science Forum Vols. 483-485, pp. 185-188. FIG. 10 shows a schematic cross-sectional structure of the SiC layer provided on the Si substrate in the above example. According to the conventional example, with a Si substrate 101 annealed to about 1300° C., a source gas including C atoms such as C₃H₈ and others is supplied to the Si substrate to carbonize the surface thereof, thereby forming a SiC layer 102. Next, a source gas including Si atoms such as Si₂Cl₆ and a source gas including C atoms such as C₈H₆ are supplied to the Si substrate annealed to 1300° C. to epitaxially grow a SiC layer 103 on the carbonized SiC layer 102.

### SUMMARY OF THE INVENTION

The carbonization of a Si substrate at a higher temperature is subjected to the influence of surface conditions thereof to form non-uniform SiC layer or produce a voids in the substrate due to consuming Si atoms in the Si substrate. For this reason, epitaxially growing a single crystal SiC thereon produces a large number of defects such as dislocation attributed to the above nonuniformity, which has made it very difficult to improve crystallinity.

The object of the present invention is to provide a method of forming a single crystal SiC layer good in crystallinity and surface morphology on a Si substrate.

One aspect of the present invention is directed to a semiconductor device which is characterized in that a first semiconductor thin film 2′ which is lower in melting point than a single crystal substrate 1 is formed on the single crystal substrate 1, and a second semiconductor thin film 3 including a semiconductor material which is different in lattice constant from the single crystal substrate and higher in melting point than the first semiconductor thin film is formed on the first semiconductor thin film and annealed at a temperature higher than the melting point of the first semiconductor thin film 2′ in order to reduce strain between the second semiconductor thin film 3′ and the single crystal substrate 1.

According to the aspect of the present invention, the first semiconductor thin film 2′ and the second semiconductor thin film 3′ refer to semiconductor thin films formed by annealing the first semiconductor thin film 2 and the second semiconductor thin film 3 respectively (to be described later).

According to the aspect of the present invention, the second semiconductor thin film 3 before being annealed is preferably amorphous and turned into a single crystal after annealing.

According to the aspect of the present invention, the first semiconductor thin film 2 before being annealed is preferably amorphous and turned into a single crystal after having been annealed.

According to the aspect of the present invention, the third semiconductor thin film having the same structure as the second semiconductor thin film 3 is preferably provided on the second semiconductor thin film 3.

According to the aspect of the present invention, a thin film including a material of which characteristics are not varied by annealing is preferably provided between the single crystal substrate 1 and the first semiconductor thin film 2.

According to the aspect of the present invention, the single crystal substrate 1 preferably includes single crystal Si.

According to the aspect of the present invention, the first semiconductor thin film 2 preferably includes SiGe.

According to the aspect of the present invention, the composition ratio of Ge included in the first semiconductor thin film is preferably 30% or more.

According to the aspect of the present invention, the second semiconductor thin film preferably includes SiC.

According to the aspect of the present invention, the third semiconductor thin film preferably includes SiC.

According to the aspect of the present invention, the third semiconductor thin film preferably includes one element of at least Ga, Al and In, and nitrogen.

The aspect of the present invention can provide a method of forming a single crystal SiC layer good in crystallinity on the Si substrate.

The aspect of the present invention can provide a high performance and low cost semiconductor device formed on a single crystal SiC layer good in crystallinity stacked on the Si substrate and a method of producing the same.

### BRIEF DESCRIPTION OF THE DRAWINGS

Embodiments of the present invention will be described in detail based on the following figures, wherein:

FIG. 1 is a schematic cross section illustrating a method of producing a semiconductor thin film according to a first embodiment of the present invention;

FIG. 2A is a schematic cross section illustrating a method of producing a semiconductor thin film in the order of steps according to the present invention shown in FIG. 1;

FIG. 2B is a schematic cross section illustrating a method of producing a semiconductor thin film in the order of steps according to the present invention shown in FIG. 1;

FIG. 2C is a schematic cross section illustrating a method of producing a semiconductor thin film in the order of steps according to the present invention shown in FIG. 1;

FIG. 3 is a schematic cross section illustrating a method of producing a semiconductor thin film according to a second embodiment of the present invention;

FIG. 4A is a schematic cross section illustrating a method of producing a semiconductor thin film in the order of steps according to the present invention shown in FIG. 3;

FIG. 4B is a schematic cross section illustrating a method of producing a semiconductor thin film in the order of steps according to the present invention shown in FIG. 3;

FIG. 4C is a schematic cross section illustrating a method of producing a semiconductor thin film in the order of steps according to the present invention shown in FIG. 3;

FIG. 5 is a schematic cross section illustrating a semiconductor device according to a third embodiment of the present invention;

FIG. 6 is a schematic cross section illustrating a semiconductor device according to a fourth embodiment of the present invention;

FIG. 7 is a schematic cross section illustrating a semiconductor device according to a fifth embodiment of the present invention;

FIG. 8 is a schematic cross section illustrating a semiconductor device according to a sixth embodiment of the present invention;

FIG. 9 is a schematic cross section illustrating a semiconductor device according to a seventh embodiment of the present invention; and

FIG. 10 is a schematic cross section illustrating a method of producing a conventional semiconductor thin film.

### DETAILED DESCRIPTION OF THE PREFERRED EMBODIMENTS

The preferred embodiments of a semiconductor device according to the present invention are stated below. That is, a SiGe layer (the first semiconductor layer 2) is formed on the single crystal Si substrate 1. In addition, a SiC layer (the second semiconductor layer 3) is formed on the SiGe layer 2 and annealed at a temperature above the melting point of the SiGe layer 2. Thus, the SiGe layer 2 is melted to relieve a strain produced between the SiC layer 3 and the Si substrate.

The preferred embodiment of a method of producing a semiconductor device according to the present invention is described below. The SiC layer 3 is amorphous before a heat treatment for melting the SiGe layer 2, and the SiC layer 3 is crystallized at the same time the SiGe layer 2 is melted.

The preferred embodiment of a method of producing a semiconductor device according to the present invention is characterized in that the SiGe layer is amorphous before a heat treatment for melting the SiGe, and SiGe is simultaneously melted and solid-phase grown. Adopting such embodiment described above improves the uniformity of the SiGe layer and the crystallinity of the single crystal SiC layer grown thereon.

In addition, the amorphous SiC layer is crystallized and thereafter epitaxially grown to be the single crystal SiC layer, thereby enables reducing the defect density of surface of the SiC layer.

Another preferred embodiment of a method of producing a semiconductor device according to the present invention is characterized in that a silicon oxide film and the single crystal Si layer are provided between the Si substrate and the SiGe layer. By adopting such embodiment, the composition ratio of Ge in the SiGe layer is not varied even by heat treatment at a high temperature, which improves the melting uniformity of SiGe and the crystallinity of the single crystal SiC layer grown thereon.

The composition ratio of Ge included in the SiGe layer is preferably 30% or more. Furthermore, in the preferred embodiment of a method of producing a semiconductor device according to the present invention, a semiconductor film including one element of at least Ga, Al and In and nitrogen is preferably formed on a crystallized SiC layer.

### [Comparison with a Conventional Method of Producing]

In general, according to reports presented till now, a single crystal SiC has been conventionally formed on a Si substrate in such a manner that the Si substrate is annealed at about 1350° C. while supplying the substrate with a source gas including C to carbonize the surface of the Si substrate to form SiC, and thereafter a single crystal SiC is grown using source gas including Si and C. In this case, the SiC layer formed by carbonization is not uniform, producing irregularity on an interface between SiC and Si, which generates crystal defects in the SiC layer, causing a drawback that surface morphology on the SiC layer is degraded.

In the specification of the present invention, as described above, a SiGe layer is formed between the SiC and the Si layer and annealed at a temperature above the melting point of the SiGe layer to relieve a strain produced between the SiC and the Si substrate, which allows avoiding the above problems.

The further detailed embodiments of a semiconductor device according to the present invention and a method of producing the same will be described below with reference to the accompanying drawings.

### First Embodiment

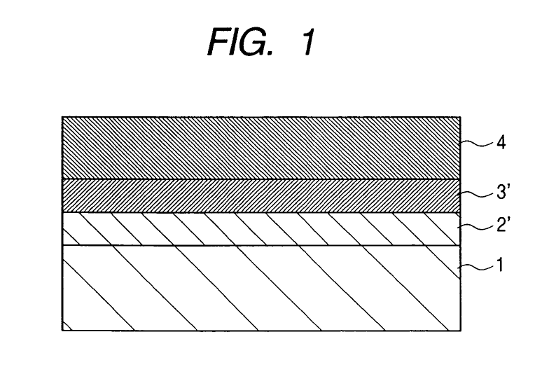

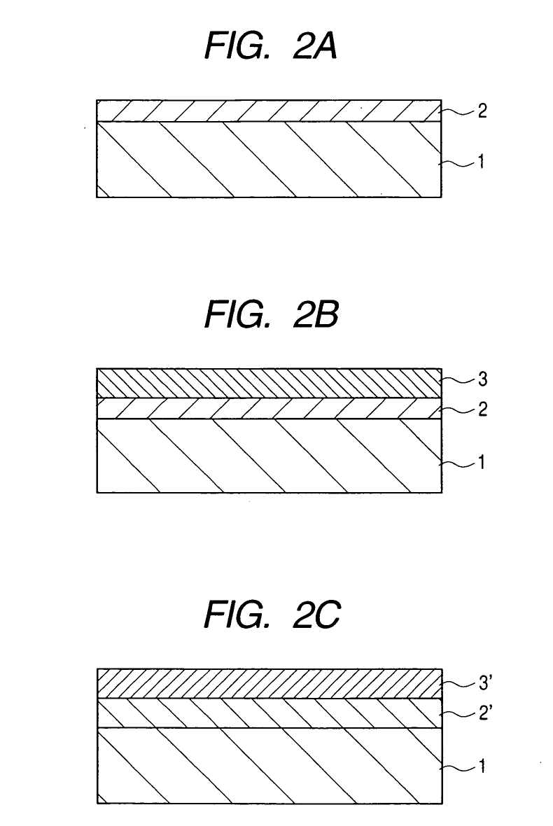

FIG. 1 is a cross section showing one embodiment of a method of producing a semiconductor thin film of the present invention. The SiGe layer 2′ is formed on the Si substrate 1. An amorphous SiC is formed thereon to form a SiC layer 3′ crystallized by a high-temperature annealing and a single crystal SiC layer is epitaxially grown. FIGS. 2A to 2C show flowcharts for a producing method to realize a semiconductor device having the structure shown in FIG. 1. First, a single crystal SiGe layer 2 is epitaxially grown on the Si substrate 1 and an amorphous SiC layer 3 is subsequently formed thereon. Next, annealing the amorphous SiC layer 3 at a high temperature to crystallize the layer to form a single crystal 3′. Thereafter, a single crystal SiC layer 4 is epitaxially grown to provide the structure shown in FIG. 1. In the present embodiment, the SiGe layer 2 corresponds to a first semiconductor thin film in the present specification and the amorphous SiC layer 3 corresponds to a second semiconductor thin film in the present specification.

A method of growing a semiconductor single crystal layer according to the present invention is described in detail based upon the present embodiment. The growing method described below will be applied to a method of growing a semiconductor single crystal layer according to the present invention as well as those in other embodiments.

### [Process Before Single Crystal Growth]

### [Cleaning]

First of all, the Si substrate 1 is cleaned to remove contaminants and native oxidation film on the surface thereof in advance. The substrate is dipped in annealed liquid mixture of, for example, ammonia, hydrogen peroxide and water to remove contaminants including heavy metals or organic substances on the surface and particles sticking to the surface thereof. In the second place, an oxidation film formed on the surface of the substrate during cleaning the substrate in liquid mixture of ammonia, hydrogen peroxide and water is removed by fluorinated acid, and immediately thereafter the substrate is rinsed in pure water, thereby the surface of the Si substrate 1 is covered with hydrogen atoms. In this state, Si atoms existing on the uppermost surface of the Si substrate 1 are bonded with hydrogen, which impedes native oxide film from being formed on the surface before growth starts after the substrate has been cleaned. In order to process hydrogen termination of the substrate surface by cleaning and prevent native oxide film from being formed on the surface, it is preferable to transfer the Si substrate in clean nitrogen after the substrate has been cleaned to prevent the surface of the substrate from being oxidized again and contaminants from sticking thereto. The present method of cleaning and transferring the substrate conducted before exiptaxial growth is applied also to the subsequent embodiments.

### [Cleaning]

The cleaned Si substrate 1 is placed in a load lock chamber and air starts to be evacuated therefrom. After air has been evacuated from the load lock chamber, the Si substrate 1 is transferred to a growth chamber via a transfer chamber. It is desirable that the growth chamber and the transfer chamber be in high vacuum or ultra-high vacuum to prevent contaminants from sticking to the surface of the substrate. Degree of vacuum is preferably about 1×10⁻⁵ Pa or less, for example. The same degree of vacuum is applied also to a growth chamber 2 described later. It is required to prevent gases including hydrogen, water, or organic contaminants from entering the transfer chamber and the growth chamber to prevent crystal defect from being produced due to the enter of oxygen or carbon in the single crystal layer formed in the growth chamber. For this reason, it is desirable to start transferring the Si substrate 1 after the degree of vacuum in the load lock chamber has fallen to about 1×10⁻⁵ Pa or less.

Even if the surface of the substrate is terminated with hydrogen, oxide film and contaminants cannot be completely prevented from forming on and sticking to the surface of the substrate respectively during transfer, so that the surface of the substrate is cleaned before epitaxial growth. The following are typical methods of cleaning: (1) annealing a semiconductor substrate in vacuum, (2) annealing a semiconductor substrate with hydrogen supplied thereto and (3) annealing a semiconductor substrate with atomic hydrogen supplied thereto.

(1) A method of annealing a semiconductor substrate in vacuum For example, annealing a Si substrate in vacuum enables native oxide film on the surface of the substrate to be removed based on the following reaction: Si+SiO2→2SiO↑.

(2) A method of annealing a semiconductor substrate with hydrogen supplied thereto

The surface of substrate can be cleaned by annealing the Si substrate with the growth chamber supplied with pure hydrogen. In the method of cleaning by annealing the substrate in vacuum described above, hydrogens terminating the surface of the substrate are desorbed at a substrate temperature of 500° C. or higher, and Si atoms exposed on the surface of the substrate react to moisture or oxygen included in the atmosphere of the growth chamber, resultantly the surface of the substrate is again oxidized. The oxide film is again reduced, increasing irregularity on the surface of the substrate along with cleaning, which causes a problem which worsens uniformity of the subsequent epitaxial growth and crystallinity. In addition, carbon dioxide or organic gas included in the atmosphere of the growth chamber sticks to the surface, which also worsens crystallinity of epitaxially grown layer due to the contamination of carbon.

On the other hand, when the Si substrate is annealed with the surface of the substrate supplied with hydrogen, even if hydrogen is desorbed from the surface of the substrate at a substrate temperature of 500° C. or higher, pure hydrogen gas is always supplied, so that Si on the surface of the substrate and hydrogen are repetitively bonded and desorbed. This impedes the Si on the surface from being oxidized again, which does not produce irregularity on the surface during cleaning, providing a pure surface condition.

To begin with, hydrogen gas is supplied to the growth chamber to perform the cleaning in a hydrogen atmosphere. It is preferable to set the substrate temperature at 500° C. or lower at which hydrogen desorbs before hydrogen gas is supplied to prevent hydrogen from desorbing from the surface of the substrate. It is preferable that the flow rate of hydrogen gas be 10 ml/min or more at which gas can be supplied with good controllability and be 100 l/min or less to safely process exhausted gas. At this point, the lower limit of partial pressure of hydrogen gas in the growth chamber is set at 10 Pa so that the gas is evenly supplied to the surface of the substrate. The upper limit may be atmospheric pressure to keep the equipment safe. After hydrogen gas has been supplied, the Si substrate 1 is annealed up to the cleaning temperature. In this case, any mechanism or structure may be used as a annealing method, provided that the Si substrate is not contaminated or temperature is significantly different in the substrate during annealing. For example, induction annealing in which high frequency is applied across a work coil and annealing by using a resistance heater can be applied, and in addition to the above, a annealing method of using radiation from a lamp may be used, in particular, as a method which enables temperature to be controlled in a short time. This annealing method may be used not only for cleaning, but for single crystal growth described later.

Annealing the substrate for a predetermined time after the Si substrate 1 has been annealed up to the cleaning temperature allows native oxide film and contaminants on the surface to be removed. It is preferable that the cleaning temperature be, for example, 600° C. or higher at which a cleaning effect can be achieved and 1000° C. or lower at which dopants in the substrate are actively diffused by heat treatment. In addition, the cleaning temperature needs to be as low as possible to reduce influence on the structure formed before epitaxial growth.

(3) A Method of Annealing a Semiconductor Substrate with Atomic Hydrogen Supplied thereto

Cleaning may be performed by using atomic hydrogen as a method enabling the cleaning temperature to be lowered. This method is capable of causing reductive reaction of oxygen by irradiating the surface of the substrate with active hydrogen atoms without increasing the substrate temperature, therefore a cleaning effect can be achieved in room temperature. For example, irradiating the surface of the substrate with a proportion of the molecules dissociated to an atomic state in hydrogen gas enables lowering the cleaning temperature. For example, if a cleaning time is taken to be 10 minutes or less, the cleaning temperature may be 650° C.

Although cleaning by using hydrogen was described above, gas such as hydrogen fluoride having an etching effect on silicon oxide film may be supplied, as other methods. The method of cleaning may be used in other embodiments.

### [Preparation for Epitaxial Growth]

After cleaning has been finished, the temperature of the substrate is lowered to a temperature at which epitaxial growth is conducted. Time is given to stabilize the temperature of the substrate at a temperature at which epitaxial growth is conducted. It is desirable, at the step for stabilizing temperature, to continue supplying hydrogen gas to keep the surface of the Si substrate 1 clean after the Si substrate 1 has been cleaned, however, hydrogen gas is effective in cooling the surface of the substrate, so that the temperature of surface of the substrate will vary with the flow rate of gas provided that annealing condition is the same. For this reason, even if the temperature of the substrate is stabilized under condition where hydrogen gas significantly different in total flow rate from gas used for epitaxial growth is supplied, the flow rate of gas varies at the time of starting epitaxial growth, which significantly varies the temperature of the substrate. It is therefore desirable to substantially equalize the flow rate of hydrogen gas used at the step for stabilizing the temperature of the substrate to the total flow rate of gas used in epitaxial growth to prevent the above phenomenon. The step for stabilizing temperature is not always provided after the temperature of the substrate has been lowered to the temperature of epitaxial growth, but, while lowering the temperature of the substrate, the flow rate of hydrogen gas may be regulated to be preferably equal to that of gas used in epitaxial growth at the time when the temperature of the substrate is lowered to that of epitaxial growth. In this case, epitaxial growth can be started immediately after the temperature of the substrate has been lowered, so that throughput can be substantially improved.

### [Growth of SiGe]

Next, hydrogen gas supplied to stabilize the temperature of the substrate is stopped and the source gas is supplied to start the epitaxial growth of the SiGe layer 2. As the source gas, the gases such as compounds of group IV elements such as silicon, germanium and others with hydrogen, chlorine or the like may be used. Those include, for example, monosilane (SiH₄), disilane (Si₂H₆), monogermane (GeH₄), dichlorosilane (SiH₂Cl₂), silicon trichloride (SiHCl₃), silicon tetrachloride (SiCl₄) and others. A method of using other gases is the same as above.

The composition ratio of Ge in the SiGe layer 2 can be controlled by varying the ratio between the flow rates of disilane and germane. For example, if the temperature of epitaxial growth is taken as 550° C., the pressure of epitaxial growth as 1 Pa, and the flow rate of disilane as 2 ml/min, setting the flow rate of germane to about 3 ml/min allows the composition ratio of Ge to be set to 15%. The temperature range in which epitaxial growth is conducted varies depending on the composition ratio of Ge in the SiGe layer. The lower limit of the temperature range is a temperature at which the source gas is decomposed at the growth surface and the SiGe growth proceeds, and the upper limit thereof is a temperature at which surface morphology on the SiGe layer betters. Since Ge is greater by 1.4% in lattice constant than Si, strain energy causes Ge to insularly and three-dimensionally grow according as the temperature of epitaxial growth rises. For this reason, if the composition ratio of Ge is high, the growth temperature needs to be lowered to grow a two-dimensionally uniform Ge. For example, a temperature range is from 300° C. to 500° C. for cases where the Ge film with a composition ratio of Ge of 100% is grown, and a temperature range is from 500° C. to 750° C. for cases where the SiGe film with a composition ratio of Ge of 15% is grown. For the growth of the SiGe film with an intermediate composition ratio of Ge, a temperature range depends on the composition ratio within these temperature ranges. The growth pressure preferably ranges from 0.1 Pa under which a growth rate is rate-limited by reaction on the surface to 10000 Pa under which reaction starts in gas phase. The SiGe layer 2 may be 1 nm or more in thickness in which the film thickness can be controlled and strain can be effectively relieved, and 100 nm or less in thickness in which surface morphology is worsened. The growth condition for the SiGe layer 2 in the subsequent embodiments is the same as the above.

The SiGe layer may be amorphous instead of single crystal. Since an amorphous SiGe layer does not produce strain attributed to difference in lattice constant between the SiGe layer and the Si substrate, enabling forming uniform SiGe layer 2. The growth temperature in this case may be 250° C. or higher at which the gas is decomposed and 300° C. or lower at which the amorphous SiGe layer is epitaxially grown. At a temperature lower than that, a growth rate is extremely lowered, so that the growth rate can be improved by using a cracking heater to promote the decomposition not only of gas by heat, but of plasma or source gas.

When doping is conducted with the growth of SiGe, as n-type doping gas, compounds of group V elements with hydrogen, chlorine, fluorine or the like may be used. Those include, for example, phosphine (PH₃), arsine (AsH₃) and so forth. When p-type doping is conducted, as the doping gas, compounds of group III elements with hydrogen, chlorine, fluorine or the like may be used. Those include, for example, diborane (B₂H₆) and others. Doping concentration can be controlled by the flow rate of doping gas. For example, for an n-type doping concentration of 1×10¹⁹ cm⁻³, the flow rate of phosphine may be 0.01 ml/min. For a p-type doping concentration of 1×10¹⁹ cm⁻³, similarly, the flow rate of diborane may be 0.005 ml/min.

The growth gas and doping gas are stopped to finish forming the SiGe layer 2. At this point, as is the case with the finish of cleaning on the surface of the substrate, clean hydrogen gas is preferably supplied to the surface of the SiGe layer 2 to prevent contaminants from sticking thereto. Next, the temperature of the substrate is varied to the SiC growth temperature. A wafer transfer chamber or another growth chamber for growing the SiC layer may be provided to grow SiC with good throughput. It is preferable that hydrogen gas be supplied to the transfer chamber and the substrate is always in the atmosphere of clean hydrogen gas to prevent contaminants from sticking to the surface of the substrate while the substrate is transferred between a plurality of growth chambers and transfer chambers.

### [Formation of Amorphous SiC]

Supplied gas is stopped after the temperature of the substrate has been stabilized at the SiC growth temperature, and the source gas for SiC is supplied to start growing the amorphous SiC layer 3. As carrier gas, H₂ or the like is used. As the source gas to be used, compounds of Si with hydrogen or chlorine and of C with hydrogen or chlorine may be used. For example, compounds of Si with hydrogen or chlorine include monosilane (SiH₄), disilane (Si₂H₆), dichlorosilane (SiH₂Cl₂), silicon trichloride (SiHCl₃), silicon tetrachloride (SiCl₄) and others. A method of using other gases is the same as above. Compounds of C with hydrogen or chlorine include methane (CH₄), ethane (C₂H₆), propane (C₃H₈), butane (C₄H₁₀), acetylene (c₂H₂) and others. A method of using other gases is the same as above.

Compounds of Si with C may be used. Examples of gases having bond between Si and C include, for example, monomethylsilane (CH₃SiH₃), dimethylsilane (CH₃)₂SiH₂), trimethylsilane ((CH₃)₃SiH), tetramethylsilane ((CH₃)₄Si), diethylsilane ((C₂H₅)₂SiH₂), triethylsilane ((C₂H₅)₃SiH), tetraethylsilane ((C₂H₄)₄Si), methyltrichlorosilane (CH₃SiCl₃), dimethyldichlorosilane ((CH₃)₂SiCl₂), trimethylchlorosilane ((CH₃)₃SiCl) and others. When CH₃SiH₃ is used as source gas and the Si substrate with an orientation of (100) is used, CH₃SiH₃ is decomposed on the Si substrate and grows with Si—C bond kept. There is a significant difference in bound energy between Si atom and C atom in SiC having a zinc blende crystal structure, therefore, although both are group IV elements, polarity is produced. Atomic layers made of C and Si respectively are stacked one on top of another to grow. However, the bond between Si and C included in the source gas is broken depending growth conditions, and Si or C can be excessive. In that case, the amount of Si and C may be adjusted by adding the source gas such as Si or C as described earlier. The temperature at which the amorphous SiC is grown preferably ranges from 500° C. at which the source gas is decomposed to 900° C. at which the amorphous SiC becomes good in surface morphology. Within this temperature range, the growth pressure preferably ranges from 0.1 Pa under which a growth rate is rate-limited by reaction on the surface to 10000 Pa under which reaction starts in gas phase.

The amorphous SiC may be formed by implanting C ions in the Si substrate. Furthermore, the ions may be implanted in the crystal SiC formed on the Si substrate to modify the crystal SiC into an amorphous SiC. Ion species to be implanted in this case may be Si or C, other than that, an electrically inactive element such as Ge or the like may be used. In doping, a doping element, such as nitrogen, aluminum or the like may be implanted to form an amorphous SiC. The thickness of amorphous SiC layer 3 preferably ranges from 1 μm which is controllable to 100 nm in which surface morphology is not degraded and the layer can uniformly crystallize. The growth conditions for the amorphous SiC layer in the subsequent embodiments is the same as the above.

In doping, as n-type doping gas, compounds of group V elements with carbon, hydrogen, chlorine, fluorine or the like may be used. Those include, for example, nitrogen (N₂), phosphine (PH₃), trimethylphosphine ((CH₃)₃P), triethylphosphine ((C₂H₅)₃P), phosphorustrichloride (PCl₃), phosphorustrifluoride (PF₃), arsin (AsH₃), diethylarsin ((C₂H₅)₂AsH), diethylarsin chloride ((C₂H₅)₂AsCl), trimethylarsin ((CH₃)₃As), triethylarsin ((C₂H₅)₃As), arsenictrichloride (AsCl₃), ammonia (NH₃), diethylamine ((C₂H₅)NH), triethylamine ((C₂H₅)₃N), trimethylamine ((CH₃)₃N) and others. As p-type doping gas, compounds of group III elements with carbon, hydrogen, chlorine, fluorine or the like may be used. Those include, for example, diborane (B₂H₆), trimethylboron ((CH₃)₃B), triethylboron ((C₂H₅)₃B), methylborondifluoride (CH₃BF₂), dimethylboron fluoride ((CH₃)₂BF), borontrichloride (BCl₃), borontrifluoride (BF₃), dimethylaluminum ((CH₃)₂AlH), trimethylaluminum ((CH₃)₃Al), triethylalumium ((C₂H₅)₃Al), methylaluminumdichloride (CH₃AlCl₂), dimethylaluminumchloride ((CH₃)₂AlCl), ethylaluminumdichloride (C₂H₅AlCl₂), diethylaluminumchloride ((C₂H₅)₂AlCl) and others.

### [Crystallization Annealing]

Next, a high temperature annealing is conducted to cause the amorphous SiC layer 3 to crystallize. As atmosphere for annealing, hydrogen, argon or others which are not doping gas may be used. The annealing temperature preferably ranges from a temperature at which the SiGe layer melts to a temperature at which the amorphous SiC starts crystal growth from solid phase. For the Ge film with a Ge composition ratio of 100%, the melting point is about 960° C. and the crystallizing temperature of the amorphous SiC is about 850° C. to 1050° C., so that annealing temperature is preferably 960° C. or higher. The upper limit of annealing temperature will be about 1420° C. which is the melting point of Si used as the substrate.

If the SiGe layer 2 on the Si substrate 1 is amorphous, the SiGe layer 2 first crystallizes at a temperature lower than that at which the amorphous SiC layer 3 crystallizes. At this point, crystallization starts at the lower surface the SiGe layer 2 contacting the Si substrate 1 and proceeds toward the interface with the amorphous SiC layer 3. When annealing temperature is subsequently increased to reach a temperature of solid phase growth of the amorphous SiC, the SiC starts crystallizing. At this point, since the surface contacting the SiGe layer 2 reflects the periodicity of crystalline array of the SiGe layer 2 to be prone to crystallize, crystallization proceeds from the lower to the upper surface. As stated earlier, the difference in lattice constant between SiC and Si is about 20%, and the difference between SiC and SiGe to which Ge large in atomic radius is added will be further greater. For that reason, strain increases around the interface between SiC and SiGe according as SiC crystallizes, which causes crystal defect such as dislocation and uneven crystallization of SiC. Then, the Ge composition ratio is adjusted so that the SiGe layer 2 starts melting substantially at the same time when the SiC starts crystallizing, which enables the SiC to crystallize between the SiC and the SiGe without strain and the single crystal SiC layer 3′ to be formed. If the crystallization temperature of the amorphous SiC is 1050° C., for example, taking the Ge composition ratio in the SiGe to be 80% allows the melting point of the SiGe to be set at about 1052° C. higher than the crystallization temperature of the amorphous SiC.

### [SiC Epitaxial Growth]

The amorphous SiC layer 3 has completed crystallization to form the single crystal SiC on the surface thereof. However, the film needs to be thin to form the single crystal SiC layer 3′ which is uniform and good in crystallinity, so that the SiC epitaxial growth is continuously conducted to form a single crystal SiC layer 4. The same source gas as that used for growing the amorphous SiC layer 3 is used for the single crystal SiC layer 4, however, the growth temperature is different. The source gas needs migrating enough and forming bond between Si and C to form the single crystal SiC, so that the growth temperature ranges from 1000° C. to 1400° C. which is the melting point of Si being the substrate material. Within this temperature range, the growth pressure preferably ranges from 0.1 Pa under which a growth rate is rate-limited by reaction on the surface to 10000 Pa under which reaction starts in gas phase. The single crystal SiC layer 4 may be 10 nm or more in thickness which can be accurately controlled and about 10 μm or less in thickness in which the layer does not warp. Doping is also the same as that in forming the amorphous SiC layer 3.

To finish the epitaxial growth for forming the single crystal SiC layer 4 the growth gas and doping gas are stopped and temperature is lowered. Lowering the temperature causes the SiGe layer 2′ to crystallize again and produces again a strain resulted from the difference in lattice constant at the interface between SiC layer 3′ and SiGe layer 2′, however, SiGe is weaker in bonding power than SiC, so that dislocation is produced not in the single crystal SiC layer 3′, but in the SiGe layer 2′, which will not degrade the crystallinity of the single crystal SiC layer 4.

As described in the present embodiment, it has been possible to form the single crystal SiC layer good in crystallinity and surface morphology on the Si substrate, which allows substantially reducing the cost of semiconductor devices such as a light emitting device and transistor using this structure as a virtual substrate.

### Second Embodiment

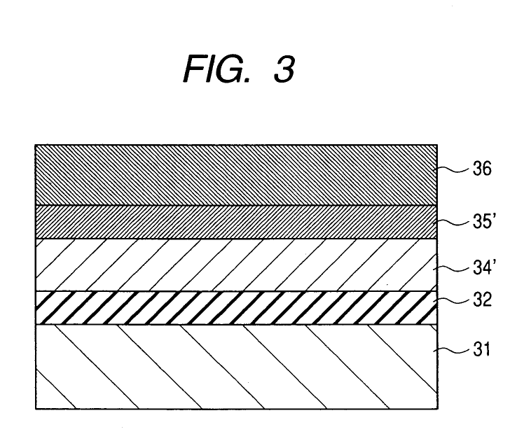

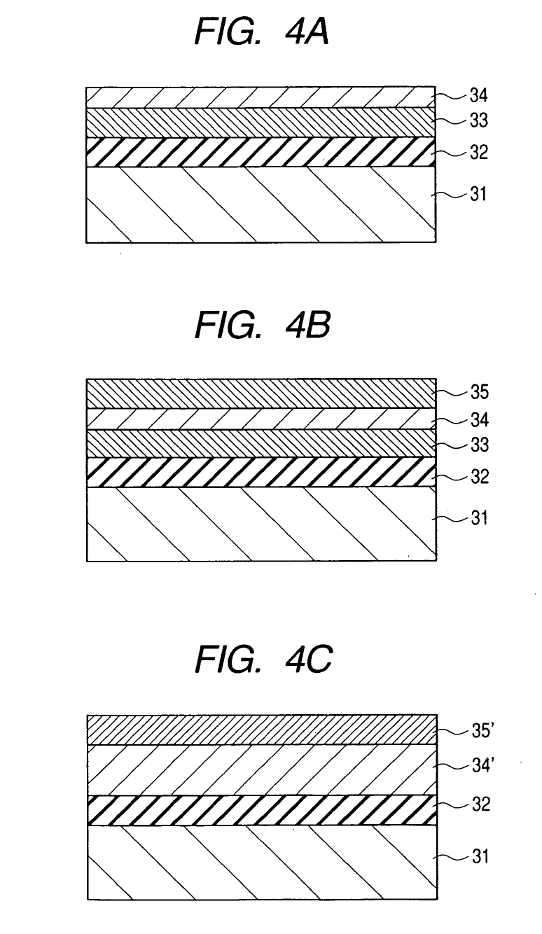

FIG. 3 is a cross section showing one embodiment of a method of producing a semiconductor thin film of the present invention. FIGS. 4A to 4C are schematic cross sections illustrating a method of producing a semiconductor thin film of the present invention shown in FIG. 3 in the order of steps. The difference from the first embodiment is that a silicon oxide film 32 and single crystal Si layer 33 are provided between the Si substrate 31 and the SiGe layer 34. The other parts of elements of the present embodiment are the same as those of the first embodiment.

A method of forming the silicon oxide film 32 and the single crystal Si layer 33 on the Si substrate 31 is the same as that of forming an ordinary SOI substrate. The silicon oxide film preferably ranges from 10 nm in thickness with consideration for stability in a high temperature annealing to 1 μm in thickness in which temperature can be controlled in annealing. The single crystal Si layer 33 is preferably 5 nm or more in thickness in which inplane uniformity can be secured, but determined depending upon the Ge composition ratio in the SiGe layer 34 and thickness thereof. In the structure of the present embodiment, the single crystal Si layer 33 and the SiGe layer 34 are stacked, on which the amorphous SiC layer 35 is stacked. After that, the SiGe layer 34 is melted by high temperature annealing, however, Ge diffuses into the single crystal Si layer 33 at a high temperature to be totally turned into the SiGe layer 34′ during annealing. The Ge composition ratio in and thickness of the SiGe layer 34′ are determined as is the case with the first embodiment, so that the Ge composition ratio in and thickness of the SiGe layer 34 and that of the single crystal Si layer 33 may be adjusted before Ge diffuses.

Unlike the first embodiment, the silicon oxide film 32 is formed on the Si substrate 31 in the present embodiment, so that Ge atoms will not diffuse into the Si substrate during high temperature annealing, which substantially improves the controllability of the Ge composition ratio in the SiGe layer 34′. Consequently, the SiGe layer 34′ does not vary in melting temperature, enabling the SiGe layer 34′ to uniformly melt and the amorphous SiC layer 35 stacked thereon to uniformly crystallize, which allows realizing a high-quality single crystal SiC layer 36.

In addition, the single crystal SiGe layer 33 may be provided immediately on the silicon oxide film 32, and the Ge composition ratio in the single crystal SiGe layer 34 formed thereon may be lowered than that in the single crystal SiGe layer 33. In that case, when the SiGe layers 33 and 34 are melted by high temperature annealing, the SiGe layer 33 starts melting and then the amorphous SiC layer crystallizes at the part where it contacts the SiGe layer 34. This permits advancing relief of strain and crystallization in parallel, significantly improving uniformity and quality of the SiC layer 35′.

### Third Embodiment

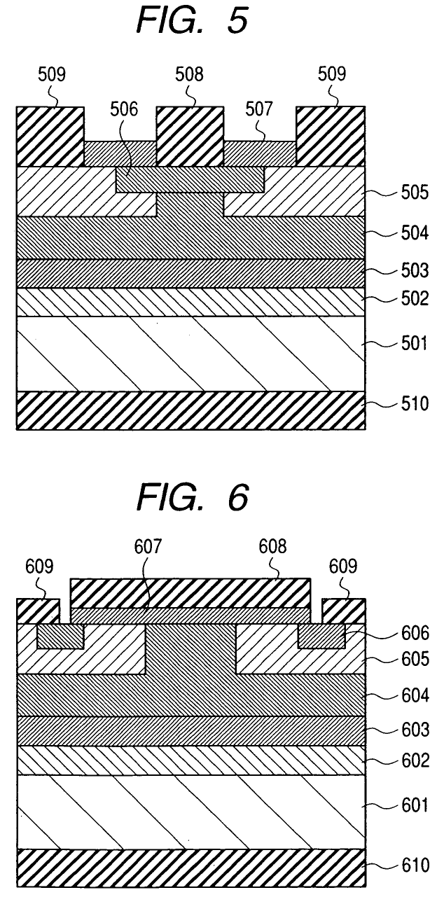

FIG. 5 is a cross section showing one embodiment to which a semiconductor thin film formed by using the present invention is applied. The present embodiment is an example in which the structure realized by the first embodiment is applied to a SiC junction FET. As is the case with the first embodiment, an n⁺SiGe layer 502, n⁺SiC layer 503 and n⁻SiC layer 504 are formed on an n⁺ Si substrate 501. Next, a p-gate region 505 and n⁺ source region 506 are formed on the SiC layer 504 by ion implantation and activation annealing. A gate electrode 509 and source electrode 508 are formed and a drain electrode 510 is formed on the other side of the substrate to obtain the structure shown in FIG. 5.

The present embodiment realizes a high performance SiC junction FET for high power and significantly reduces cost as compared with the cases where an ordinary SiC substrate is used.

### Fourth Embodiment

FIG. 6 is a cross section showing another embodiment to which a semiconductor thin film formed by using the present invention is applied. The present embodiment is an example in which the structure realized by the first embodiment is applied to a SiC MOSFET. As is the case with the first embodiment, an n⁺SiGe layer 602, n⁺SiC layer 603 and n⁻SiC layer 604 are formed on an n⁺Si substrate 601. Next, a p-body region 605 and n⁻ source region 606 are formed on the SiC layer 604 by ion implantation and activation annealing. Next, a gate insulating film 607, gate electrode 608 and source electrode 609 are formed and a drain electrode 610 is formed on the other side of the substrate to obtain the structure shown in FIG. 6.

The present embodiment realizes a high performance SiC MOSFET for intermediate electric power and high-speed control and significantly reduces cost compared with the cases where an ordinary SiC substrate is used.

### Fifth Embodiment

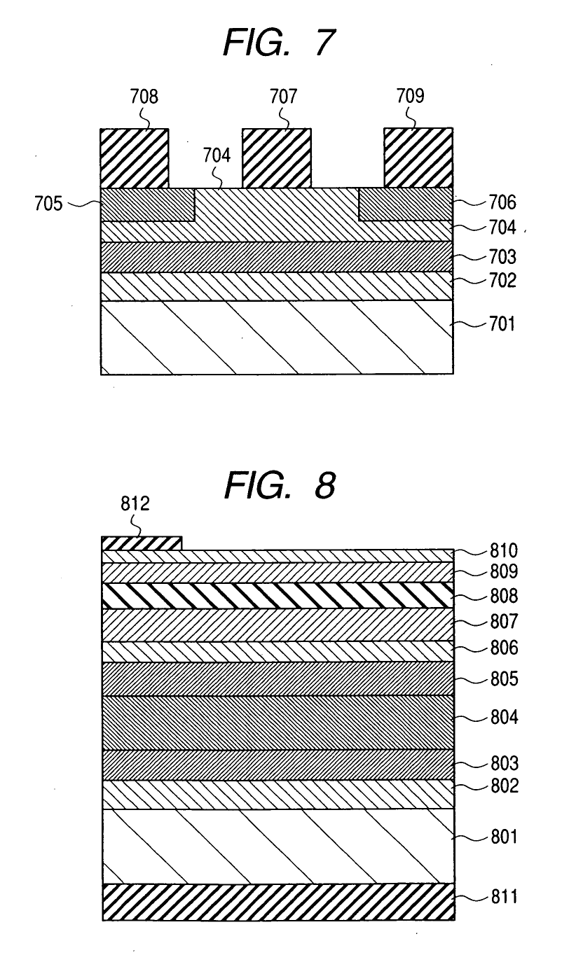

FIG. 7 is a cross section showing another embodiment to which a semiconductor thin film formed by using the present invention is applied. The present embodiment is an example in which the structure realized by the first and the second embodiment is applied to a SiC MESFET. Although a description is made below based on the structure in the first embodiment, needless to say, the structure in the second embodiment may be similarly applied. As is the case with the first embodiment, an n⁺SiGe layer 702, n⁺SiC layer 703 and n⁻SiC layer 704 are formed on an n⁺Si substrate 701. Next, an n⁺ source region 705 and n⁺ drain region 706 are formed on the SiC layer 704 by ion implantation and activation annealing. Next, a gate electrode 707 and source electrode 708 are formed and a drain electrode 709 is formed on the other side of the substrate to obtain the structure shown in FIG. 7.

The present embodiment realizes a high performance SiC MESFET for high frequency and significantly reduces cost compared with the cases where an ordinary SiC substrate is used.

### Sixth Embodiment

FIG. 8 is a cross section showing another embodiment to which a semiconductor thin film formed by using the present invention is applied. The present embodiment is an example in which the structure realized by the first embodiment is applied to an LED using a GaN. As is the case with the first embodiment, an n-SiGe layer 802, n-SiC layer 803 and n-SiC layer 804 are formed on n-Si substrate 801. Next, a GaN/AlN multi-layered film 805 is formed and n-GaN layer 806, InGaN multiple quantum well 807, p-AlGaN layer 808, p-GaN layer 809 and, as usual, a surface layer 810 are sequentially grown in this order. Electrodes 811 and 812 are formed on parts except light emitting parts of the rear and front faces to obtain the structure in FIG. 8.

The present embodiment realizes an LED using a high performance GaN for various types of lightings and significantly reduces cost as compared with the cases where an ordinary SiC substrate is used. The substrate is conductive so that an electrode can be provided on the other side thereof, and a chip can be smaller in area than an LED using a sapphire substrate, which enables downsizing the LED and reducing cost.

### Seventh Embodiment

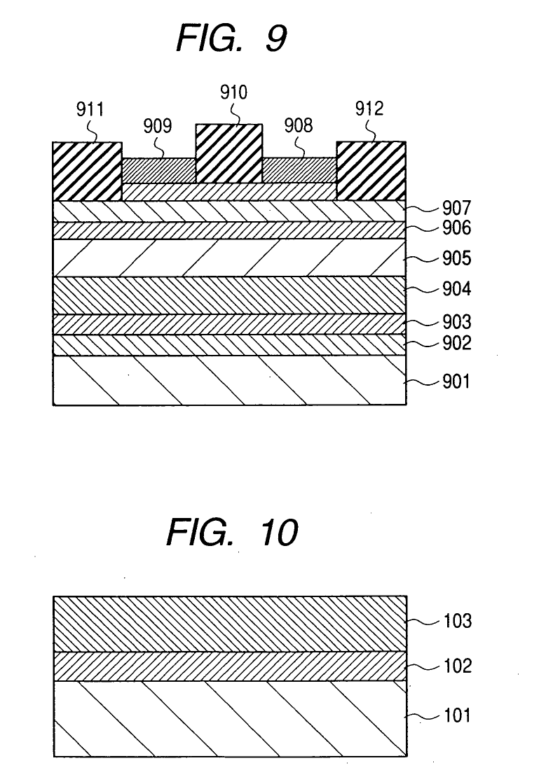

FIG. 9 is a cross section showing another embodiment to which a semiconductor thin film formed by using the present invention is applied. The present embodiment is an example in which the structure realized by the first and the second embodiment is applied to an HEMT using a GaN. Although a description is made below based on the structure in the first embodiment, needless to say, the structure in the second embodiment may be similarly applied. As is the case with the first embodiment, an i-SiGe layer 902, i-SiC layer 903, i-SiC layer 904 and i-SiC layer 905 are formed on a high-resistance Si substrate 901. Next, an AlN 905 which is 10 μm or more in thickness is formed, and an i-GaN layer 906, n-AlGaN 907 and n-GaN layer 908 are epitaxially grown in this order. A gate electrode 910, source electrode 911 and drain electrode 912 are formed to obtain the structure in FIG. 9.

The present embodiment realizes a HEMT using a high performance GaN for very high-speed space communication and significantly reduces cost compared with the cases where an ordinary SiC substrate is used.

Several embodiments according to the present invention are described above. These advantages are summarized below.

(1) A method of forming a semiconductor thin film including the steps of forming on a single crystal substrate a first semiconductor thin film lower in melting point than the single crystal substrate, forming a second semiconductor thin film including a semiconductor material different in lattice constant from the single crystal substrate and higher in melting point than the first semiconductor thin film on the first semiconductor thin film and annealing at a temperature higher than the melting point of the first semiconductor thin film to reduce strain between the second semiconductor thin film and the single crystal substrate.

(2) The method of forming a semiconductor thin film characterized in that the second semiconductor thin film is amorphous before being annealed and turned into a single crystal after having been annealed

(3) The method of forming a semiconductor thin film characterized in that the first semiconductor thin film is amorphous before being annealed and turned into a single crystal after having been annealed.

(4) The method of forming a semiconductor thin film characterized in that a third semiconductor thin film having the same structure as the second semiconductor thin film is provided on the second semiconductor thin film.

(5) The method of forming a semiconductor thin film characterized in that a thin film including a material of which characteristics are not carried by annealing is provided between the single crystal substrate and the first semiconductor thin film.

(6) The method of forming a semiconductor thin film characterized in that the single crystal substrate includes single crystal silicon Si.

(7) The method of forming a semiconductor thin film characterized in that the first semiconductor thin film includes SiGe.

(8) The method of forming a semiconductor thin film characterized in that the composition ratio of Ge included in the first semiconductor thin film is 30% or more.

(9) The method of forming a semiconductor thin film characterized in that the second semiconductor thin film includes SiC.

(10) The method of forming a semiconductor thin film characterized in that the third semiconductor thin film comprises SiC.

(11) The method of forming a semiconductor thin film characterized in that the third semiconductor thin film includes one element of at least Ga, Al and In, and nitrogen.

As is clear from the several embodiments described above, according to the present invention, a single crystal SiC layer good in crystallinity and surface morphology can be formed on the Si substrate, so that cost can be significantly reduced with the performances of a semiconductor device using this structure maintained.

Although there have been described several preferred embodiments according to the present invention, it will be understood that the present invention is not limited to the above embodiments and many design changes can be made therein without departing from the sprit of our invention.

What is claimed is:

1. A method of forming semiconductor multi-layered structure comprising the steps of:
forming a first semiconductor thin film on a single crystal substrate, the first semiconductor thin film being lower in melting point than the single crystal substrate and being a single crystal;
forming a second semiconductor thin film on the first semiconductor thin film, the second semiconductor thin film including a semiconductor material different in lattice constant from the single crystal substrate and higher in melting point than the first semiconductor thin film; and
annealing the second semiconductor thin film at a temperature higher than the melting point of the first semiconductor thin film to turn the second semiconductor thin film into a single crystal.

2. The method of forming semiconductor multi-layered structure according to claim 1, wherein the second semiconductor thin film is amorphous before the annealing step and turned into a single crystal after the annealing step.

3. The method of forming semiconductor multi-layered structure according to claim 1, wherein the first semiconductor thin film is amorphous before being annealed and turned into a single crystal after having been annealed.

4. The method of forming semiconductor multi-layered structure according to claim 2, wherein the first semiconductor thin film is amorphous before being annealed and turned into a single crystal after having been annealed.

5. The method of forming semiconductor multi-layered structure according to claim 1, further comprising the step of forming a third semiconductor thin film on the second semiconductor thin film, the third semiconductor thin film having the same structure as the second semiconductor thin film.

6. The method of forming semiconductor multi-layered structure according to claim 2, further comprising the step of forming a third semiconductor thin film on the second semiconductor thin film, the third semiconductor thin film having the same structure as the second semiconductor thin film.

7. The method of forming semiconductor multi-layered structure according to claim 3, further comprising the step of forming a third semiconductor thin film on the second semiconductor thin film, the third semiconductor thin film having the same structure as the second semiconductor thin film.

8. The method of forming semiconductor multi-layered structure according to claim 1, wherein a thin film including an inorganic material of which characteristics are not varied by annealing at a temperature higher than the melting point of the first semiconductor thin film at the annealing step is provided between the single crystal substrate and the first semiconductor thin film.

9. The method of forming semiconductor multi-layered structure according to claim 2, wherein a thin film including an inorganic material of which characteristics are not varied by annealing at a temperature higher than the melting point of the first semiconductor thin film at the annealing step is provided between the single crystal substrate and the first semiconductor thin film.

10. The method of forming semiconductor multi-layered structure according to claim 3, wherein a thin film including an inorganic material of which characteristics are not varied by annealing at a temperature higher than the melting point of the first semiconductor thin film at the annealing step is provided between the single crystal substrate and the first semiconductor thin film.

11. The method of forming semiconductor multi-layered structure according to claim 4, wherein a thin film including an inorganic material of which characteristics are not varied by annealing at a temperature higher than the melting point of the first semiconductor thin film at the annealing step is provided between the single crystal substrate and the first semiconductor thin film.

12. The method of forming semiconductor multi-layered structure according to claim 1, wherein the single crystal substrate includes single crystal silicon (Si).

13. The method of forming semiconductor multi-layered structure according to claim 1, wherein the first semiconductor thin film includes SiGe.

14. The method of forming semiconductor multi-layered structure according to claim 13, wherein the composition ratio of Ge included in the first semiconductor thin film is 30% or more.

15. The method of forming semiconductor multi-layered structure according to claim 1, wherein the second semiconductor thin film includes SiC.

16. The method of forming semiconductor multi-layered structure according to claim 7, wherein the third semiconductor thin film includes SiC.

17. The method of forming semiconductor multi-layered structure according to claim 7, wherein the third semiconductor thin film includes one element of at least Ga, Al and In, and nitrogen.
